(19) United States
(12) Patent Application Publication
(10) Pub. No.: US 2008/0280216 A1
(43) Pub. Date: Nov. 13, 2008

(54) METHOD OF FORMING A HARD MASK PATTERN IN A SEMICONDUCTOR DEVICE

(75) Inventors: Sang Min KIM, Seoul (KR); Woo Yung JUNG, Seoul (KR); Choi Dong KIM, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/967,131

(22) Filed: Dec. 29, 2007

(30) Foreign Application Priority Data
May 11, 2007 (KR) 2007-45991

(51) Int. Cl. G03F 1/00

(52) U.S. Cl. 430/5

(57) ABSTRACT

In a method of forming hard mask patterns in a semiconductor device, an etch mask has a pitch less than a resolution limitation of exposure equipment. The method includes forming first hard mask patterns through an exposure process utilizing photoresist patterns, forming a separation layer on a resulting structure including the first hard mask patterns, forming a second hard mask pattern in a space between the first hard mask patterns, and removing the exposed separation layer.

### CROSS-REFERENCE TO RELATED APPLICATIONS

This application claims priority from Korean Patent Application No. 2007-45991, filed on May 11, 2007, the contents of which are incorporated herein by reference in its entirety.

### BACKGROUND OF THE INVENTION

The present invention relates to a method of manufacturing a semiconductor device, and more particularly relates to a method of forming mask patterns having a pitch less than a resolution limitation of exposing equipment.

In a process for fabricating a semiconductor device using exposure equipment, a minimal pitch between patterns formed in a photolithography process depends on a wavelength of light utilized in the exposure equipment. Therefore, as semiconductor devices become more integrated, light having a wavelength shorter than that of light which is currently used for semiconductor fabrication is required to form patterns having a smaller pitch. To this end, X-ray or E-beam may be used. However, the use of X-ray or E-beam has not yet been commercialized due to technical problems, productivity issues and the like. To address the above limitation, a dual exposing/etching technology (DEET) has been proposed.

FIG. 1A to FIG. 1C are views of a semiconductor device for illustrating a dual exposing/etching technology. As shown in FIG. 1A, a first photoresist PR1 is applied on a semiconductor substrate 10 on which a to-be-etched layer 11 is formed. The first photoresist PR1 is then patterned through an exposing process and a developing process. Subsequently, the to-be-etched layer 11 is etched using the patterned first photoresist PR1 as a mask. A line width of the etched to-be-etched layer 11 is 150 nm and a space width is 50 nm.

Subsequently, the first photoresist PR1 is removed and a second photoresist PR2 is applied on the entire structure. The second photoresist PR2 is then patterned through an exposing process and a developing process such that the to-be-etched layer 11 is partially exposed as shown in FIG. 1B.

Then, as shown in FIG. 1C, the to-be-etched layer 11 is re-etched using the patterned second photoresist PR2 as the mask to form the finished patterns having a space width and a line width of 50 nm. Finally, the second photoresist PR2 is removed.

In the dual exposing/etching technology as described above, the overlay accuracy in the exposing process for the second photoresist PR2 is directly linked with a variation of a critical dimension (CD) of the finished pattern. In practice, since it is difficult to control the overlay accuracy of the exposure equipment below 10 nm, the variation of the critical dimension (CD) of the finished pattern is not effectively reduced. In addition, it is difficult to control an optical proximity correction due to a separation of circuits caused by the dual exposure.

### SUMMARY OF THE INVENTION

An object of the present invention is to provide a method of forming hard mask patterns of a semiconductor device, in which first hard mask patterns are formed through an exposure process utilizing photoresist patterns, a separation layer is formed on a resulting structure including the first hard mask patterns, a second hard mask pattern is formed in a space between the first hard mask patterns, and the separation layer that is exposed between the second hard mask pattern is removed. Accordingly, a mask having a pitch less than the resolution limit of exposure equipment can be formed.

A method of forming hard mask patterns in a semiconductor device according to one embodiment of the present invention comprises the steps of forming a to-be-etched layer on a semiconductor substrate; forming first hard mask patterns on the to-be-etched layer; forming a separation layer on the to-be-etched layer including the first hard mask patterns; forming a hard mask layer in a space between the first hard mask patterns; and removing the separation layer formed on an upper surface and side walls of the first hard mask pattern to form second hard mask patterns consisting of the separation layer and the hard mask layer.

The to-be-etched layer is formed by laminating sequentially an amorphous carbon layer and a silicon oxynitride (SiON) layer, and the first hard mask pattern is formed of a polysilicon layer, a nitride layer or an oxide layer.

Preferably, the first hard mask patterns are formed such that a ratio between a critical dimension of the pattern and a distance between the patterns is approximately 1:3.

The separation layer is formed from carbon based polymer, and the hard mask layer is formed of a multi function hard mask layer containing silicon (Si) ingredients. Preferably, the hard mask layer contains silicon (Si) ingredients of approximately 15 to 50 weight % with respect to the total weight.

The step of forming the hard mask layer comprises the step of forming the hard mask layer on the entire resulting structure including the separation layer and the step of performing an etch-back process to expose an upper portion of the separation layer.

A method of forming hard mask patterns in a semiconductor device according to another embodiment of the present invention comprises forming first hard mask patterns on a semiconductor substrate; forming a separation layer on a resulting structure including the first hard mask patterns such that a space between the first hard mask patterns is not filled completely with the separation layer; forming second hard mask patterns, each of the second hard mask patterns being formed in a space between the first hard mask patterns; and removing the exposed separation layer to expose the semiconductor substrate.

The first hard mask pattern is formed such that a critical dimension of the first hard mask pattern is substantially the same as a thickness of the separation layer. The first hard mask patterns are formed such that a ratio between a critical dimension of the pattern and a distance between the patterns is approximately 1:3.

Forming the second hard mask patterns comprises forming the second hard mask patterns on a resulting structure including the separation layer; and performing an etch-back process to expose an upper portion of the separation layer.

A method of forming hard mask patterns in a semiconductor device according to another embodiment of the present invention comprises forming first hard mask patterns on a semiconductor substrate, wherein a line width of the first hard mask patterns is smaller than a space formed between the first hard mask patterns; forming a separation layer on the semiconductor substrate and the first hard mask patterns, wherein the separation layer is formed to have a substantially uniform thickness such that the space formed between the first hard mask patterns is not filled completely with the separation layer; forming a hard mask layer over the separation layer, wherein the hard mask layer fills in the space formed between the first hard mask patterns; etching the hard mask layer to expose an upper surface of the separation layer, wherein second hard mask patterns are formed in the space between the first hard mask patterns; and removing the exposed separation layer to expose the semiconductor substrate.

The first hard mask pattern is formed such that a critical dimension of the first hard mask pattern is substantially the same as a thickness of the separation layer. The first hard mask patterns are formed such that a ratio between a critical dimension of the pattern and a distance between the patterns is approximately 1:3.

### BRIEF DESCRIPTION OF THE DRAWINGS

The above and other features and advantages of the present invention will become readily apparent by reference to the following detailed description when considered in conjunction with the accompanying drawings wherein:

FIG. 1A to FIG. 1C are views of a semiconductor device for illustrating a dual exposing/etching technology according to the prior art; and

FIG. 2 to FIG. 7B are sectional views and scanning electron microscope (SEM) photographs of a semiconductor device for illustrating a method of forming hard mask patterns in a semiconductor device according to one embodiment of the present invention.

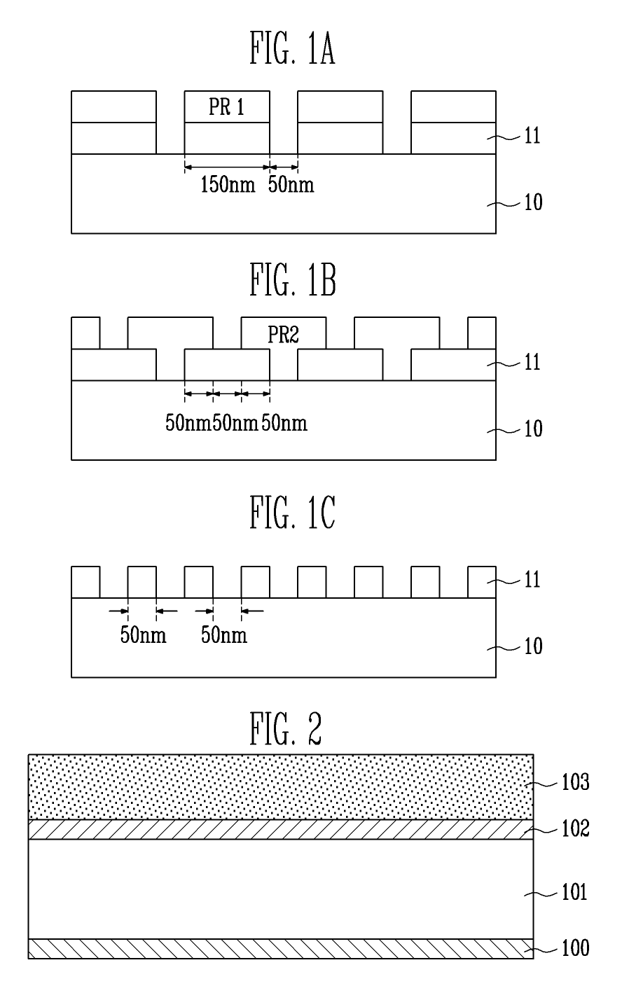

### DESCRIPTION OF SPECIFIC EMBODIMENTS

Embodiments of the present invention will be explained in detail with reference to the accompanying drawings. The scope of the present invention is not limited to the embodiment described below, but can be embodied variously.

FIG. 2 to FIG. 7B are sectional views and scanning electron microscope (SEM) photographs of a semiconductor device for illustrating a method of forming hard mask patterns in a semiconductor device according to one embodiment of the present invention.

Referring to FIG. 2, a first to-be-etched layer 101 and a second to-be-etched layer 102 are sequentially formed on a semiconductor substrate 100. In one embodiment, the first to-be-etched layer 101 and the second to-be-etched layer 102 are laminated on a semiconductor substrate 100. Preferably, the first to-be-etched layer 101 is formed of an amorphous carbon layer and the second to-be-etched layer 102 is formed of a silicon oxynitride (SiON) layer.

A first hard mask layer 103 is formed on the entire structure including the second to-be-etched layer 102. Preferably, the first hard mask layer 103 is formed of a polysilicon layer. The first hard mask layer 103 may be formed of a nitride layer or an oxide layer in place of the polysilicon layer. Preferably, the first hard mask layer 103 has a thickness of 400 to 2,000 Å.

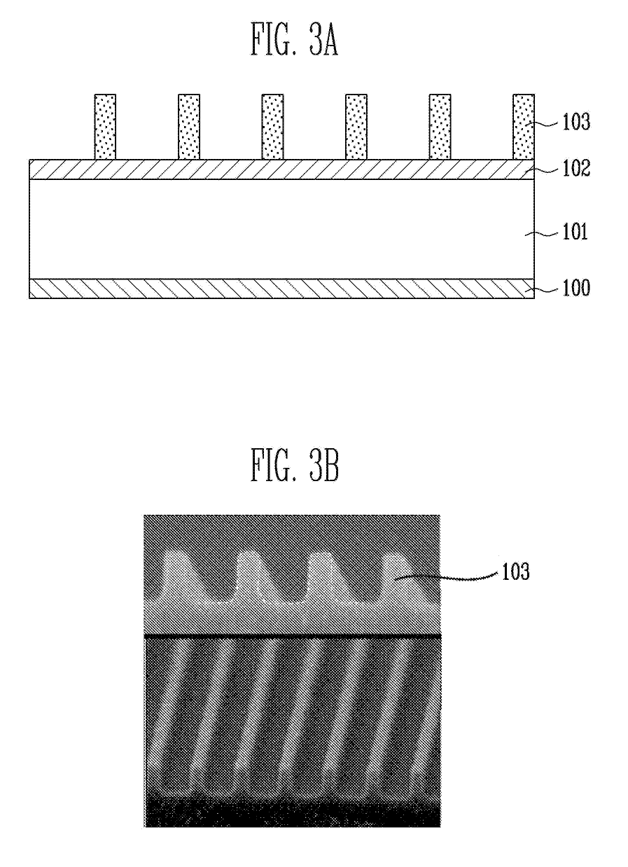

Referring to FIG. 3A and FIG. 3B, a photoresist pattern is formed on the first hard mask layer 102. An etching process using the photoresist pattern is then carried out to form first hard mask patterns 103. The first hard mask patterns 103 are formed such that a ratio between a critical dimension of the pattern and a distance between the patterns, i.e., a ratio between a line and a space, is approximately 1:3.

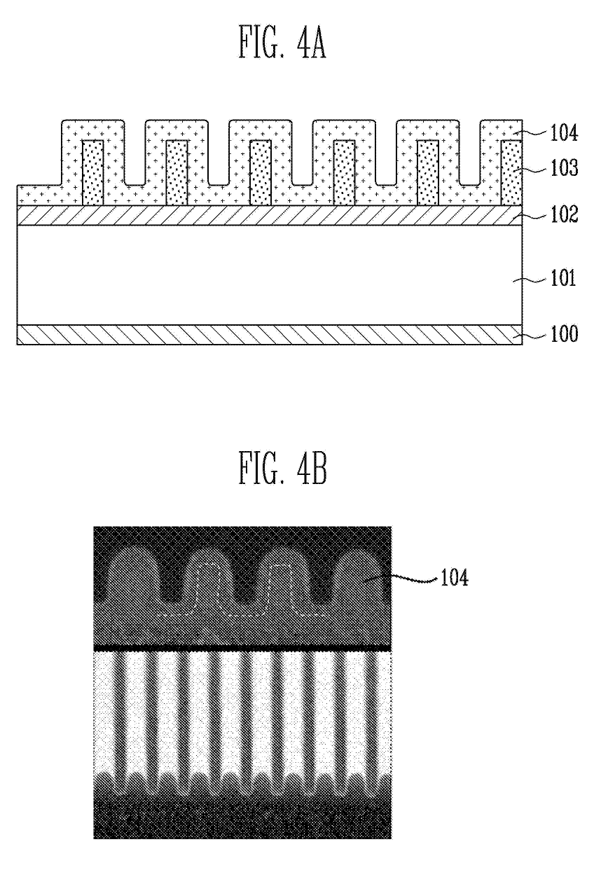

Referring to FIG. 4A and FIG. 4B, a separation layer 104 is formed on the second to-be-etched layer 102 including the first hard mask patterns 103. The separation layer 104 is formed on an upper surface and side walls of the first hard mask pattern 103 and in a space between the first hard mask patterns 103 with a uniform thickness. Preferably, the separation layer 104 has a thickness which is the same as a critical dimension of the first hard mask pattern 103. Thus, a space still exists in the separation layer 104 between adjacent first hard mask patterns 103. The separation layer 104 is preferably formed from carbon based polymer.

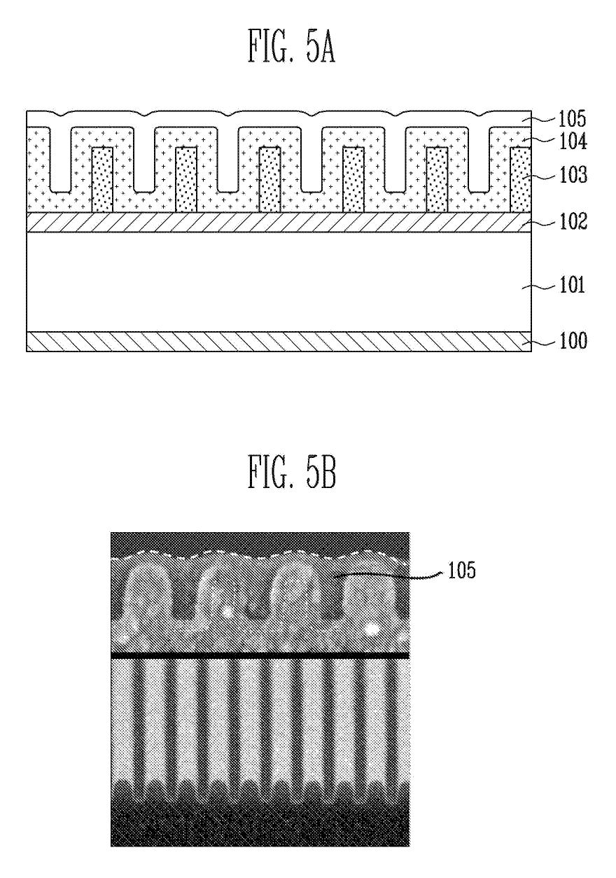

Referring to FIG. 5A and FIG. 5B, a second hard mask layer 105 is formed on the entire resulting structure including the separation layer 104. Preferably, the second hard mask layer 105 has a thickness of 500 to 2,000 Å. The second hard mask layer 105 is preferably formed of a multi function hard mask layer containing silicon (Si) ingredients of 15 to 50 weight % with respect to the total weight. Since the second hard mask layer 105 contains silicon ingredients, it is possible to increase an etching selection ratio between the second hard mask and another layer when a subsequent process for removing the separation layer is preformed.

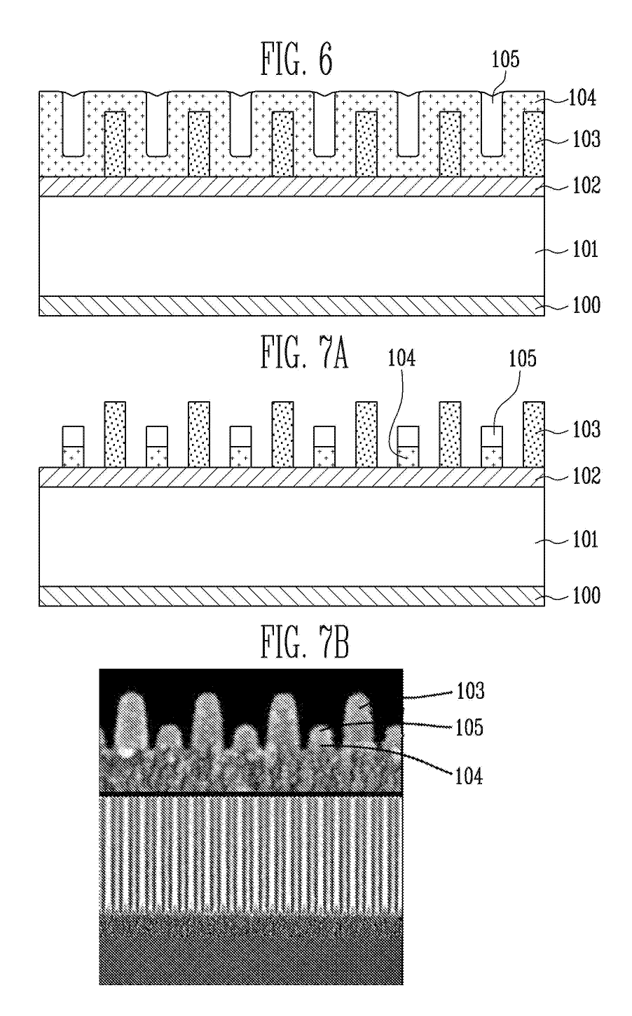

Referring to FIG. 6, an etch-back process is performed to remove the second hard mask layer 105 formed on the first hard mask patterns 103. The second hard mask layer 105 remains in the space in the separation layer between adjacent first hard mask patterns 103.

Referring to FIG. 7A and FIG. 7B, an etching process is carried out to remove the separation layer formed on an upper surface and side walls of the first hard mask patterns 103. It is preferable to perform a wet etching process to remove the separation layer. It is preferable that the process for removing the separation layer utilizes a difference between an etching ratio of the first hard mask patterns 103 and an etching ratio of the separation layer, and a difference between an etching ratio of the second hard mask layer 105 and an etching ratio of the separation layer. Due to the above process, a second hard mask pattern 105 and 104 is formed in a space between the first hard mask patterns 103.

Although not shown in the drawings, an etching process using the first hard mask pattern 103 and the second hard mask pattern 105 and 104 is performed to etch sequentially the second to-be-etched layer 102 and the first to-be-etched layer 101.

According to one embodiment of the present invention, in the process for forming hard mask patterns in a semiconductor device, first hard mask patterns are formed through an exposure process in which photoresist patterns are utilized, a separation layer is formed on the entire structure including the first hard mask patterns such that a space exists in the separation layer between the first hard mask patterns, and a second hard mask pattern is formed in the space between the first hard mask patterns. The exposed separation layer is removed such that a mask having a pitch less than a resolution limitation of exposure equipment used to fabricate the semiconductor device can be formed.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of forming hard mask patterns in a semiconductor device, the method comprising:
forming a to-be-etched layer over a semiconductor substrate;
forming first hard mask patterns over the to-be-etched layer;
forming a separation layer over the to-be-etched layer including the first hard mask patterns;
forming a hard mask layer in a space between the first hard mask patterns; and
removing the separation layer formed on an upper surface and side walls of the first hard mask pattern to form second hard mask patterns comprising the separation layer and the hard mask layer.

2. The method of claim 1, wherein the to-be-etched layer is formed by laminating sequentially an amorphous carbon layer and a silicon oxynitride (SiON) layer.

3. The method of claim 1, wherein the first hard mask pattern comprises a polysilicon layer, a nitride layer or an oxide layer.

4. The method of claim 1, wherein the first hard mask patterns are formed such that a ratio between a critical dimension of the pattern and a distance between the patterns is approximately 1:3.

5. The method of claim 1, wherein the separation layer comprises a carbon based polymer.

6. The method of claim 1, wherein the hard mask layer comprises a multi function hard mask layer containing silicon (Si) ingredients.

7. The method of claim 6, wherein the hard mask layer comprises silicon (Si) ingredients of 15 to 50 weight % with respect to the total weight.

8. The method of claim 1, wherein forming the hard mask layer comprises:
forming the hard mask layer on a resulting structure including the separation layer; and
performing an etch-back process to expose an upper portion of the separation layer.

9. A method of forming hard mask patterns in a semiconductor device, the method comprising:
forming first hard mask patterns on a semiconductor substrate;
forming a separation layer on a resulting structure including the first hard mask patterns such that a space between the first hard mask patterns is not filled completely with the separation layer;
forming second hard mask patterns, each of the second hard mask patterns being formed in a space between the first hard mask patterns; and
removing the exposed separation layer to expose the semiconductor substrate.

10. The method of claim 9, wherein the first hard mask pattern is formed such that a critical dimension of the first hard mask pattern is substantially the same as a thickness of the separation layer.

11. The method of claim 9, wherein the first hard mask patterns comprise a polysilicon layer, a nitride layer or an oxide layer.

12. The method of claim 9, wherein the first hard mask patterns are formed such that a ratio between a critical dimension of the pattern and a distance between the patterns is approximately 1:3.

13. The method of claim 9, wherein the separation layer comprises a carbon based polymer.

14. The method of claim 9, wherein the second hard mask patterns comprise a multi function hard mask layer containing silicon (Si) ingredients.

15. The method of claim 14, wherein the second hard mask patterns comprises silicon (Si) ingredients of 15 to 50 weight % with respect to a total weight.

16. The method of claim 9, wherein forming the second hard mask patterns comprises:
forming the second hard mask patterns on a resulting structure including the separation layer; and
performing an etch-back process to expose an upper portion of the separation layer.

17. A method of forming hard mask patterns in a semiconductor device, the method comprising:
forming first hard mask patterns on a semiconductor substrate, wherein a line width of the first hard mask patterns is smaller than a space formed between the first hard mask patterns;
forming a separation layer on the semiconductor substrate and the first hard mask patterns, wherein the separation layer is formed to have a substantially uniform thickness such that the space formed between the first hard mask patterns is not filled completely with the separation layer;
forming a hard mask layer over the separation layer, wherein the hard mask layer fills in the space formed between the first hard mask patterns;
etching the hard mask layer to expose an upper surface of the separation layer, wherein second hard mask patterns are formed in the space between the first hard mask patterns; and
removing the exposed separation layer to expose the semiconductor substrate.

18. The method of claim 17, wherein the first hard mask pattern is formed such that a critical dimension of the first hard mask pattern is substantially the same as a thickness of the separation layer.

19. The method of claim 17, wherein the first hard mask patterns comprise a polysilicon layer, a nitride layer or an oxide layer.

20. The method of claim 17, wherein the first hard mask patterns are formed such that a ratio between a critical dimension of the pattern and a distance between the patterns is approximately 1:3.

21. The method of claim 17, wherein the separation layer comprises a carbon based polymer.
